(19) United States
(12) Patent Application Publication
(10) Pub. No.: US 2026/0221387 A1
(43) Pub. Date: Jul. 30, 2026

(54) METHOD FOR PLASMA ETCHING PROCESS

(71) Applicant: Tokyo Electron Limited, Tokyo (JP)

(72) Inventors: Adam Pranda, Albany, NY (US); Yusuke Lent-Yoshida, Albany, NY (US); Yun Han, North Chelmsford, MA (US)

(21) Appl. No.: 19/039,215

(22) Filed: Jan. 28, 2025

(51) Int. Cl. H01J 37/32; H01L 21/3065; H01L 21/308

(52) U.S. Cl. CPC H01J 37/32146; H01J 37/32834; H10P 50/242; H10P 50/691; H01J 2237/334

(57) ABSTRACT

A method is provided for plasma etching in a semiconductor processing chamber. The method includes evacuating a plasma processing chamber using a vacuum pump while flowing multiple gases into the chamber. A cyclic plasma etching process is performed on a substrate through multiple cycles. Each cycle includes applying a first set of pulses at a first SP level to an SP electrode over a first time duration, and applying a second set of pulses at a first BP level to a BP electrode over a second time duration, with both sets of pulses having the same frequency. The SP electrode couples to a first reference potential lower than the first SP level for a third duration, while the BP electrode couples to a second reference potential lower than the first BP level for a fourth duration. These durations are determined based on flow rate of gases, speed of vacuum pump, and volume of processing chamber.

### TECHNICAL FIELD

The present invention relates generally to a method of plasma processing a substrate, and, in particular embodiments, to a method of fabricating devices with high aspect ratio features.

### BACKGROUND

Generally, a semiconductor device, such as an integrated circuit (IC) is fabricated by sequentially depositing and patterning layers of dielectric, conductive, and semiconductor materials over a substrate to form a network of electronic components and interconnect elements (e.g., transistors, resistors, capacitors, metal lines, contacts, and vias) integrated in a monolithic structure. Many of the processing steps used to form the constituent structures of semiconductor devices are performed using plasma processes.

The semiconductor industry has repeatedly reduced the minimum feature sizes in semiconductor devices to a few nanometers to increase the packing density of components. Accordingly, the semiconductor industry increasingly demands plasma processing technology to provide processes for patterning features with accuracy, precision, and profile control, often at nanometer scale dimensions. Meeting this challenge along with the uniformity and repeatability needed for high volume IC manufacturing requires further innovations of plasma processing technology.

### SUMMARY

In accordance with one aspect of the present invention, a method is provided for plasma etching. The method includes evacuating a plasma processing chamber using a vacuum pump while flowing multiple gases into the chamber. A cyclic plasma etching process is performed on a substrate through multiple cycles. Each cycle includes applying a first set of pulses at a first SP level to an SP electrode over a first time duration, and applying a second set of pulses at a first BP level to a BP electrode over a second time duration, with both sets of pulses having the same frequency. The SP electrode and BP electrode are then coupled to respective reference potentials lower than their first levels for durations determined by gas flow rate, vacuum pump speed, and processing chamber volume.

In accordance with another aspect of the present invention, a method is provided for etching a substrate. The method includes forming a mask layer over a layer-to-be-etched of a substrate to define an etch region in a plasma processing chamber. After evacuating the chamber and flowing gases, a cyclic plasma etching process is performed by applying pulses to a source power electrode to generate plasma and to a bias power electrode to direct ions toward the substrate for etching. Between cycles, power to both electrodes is reduced to evacuate etch byproducts from the processing chamber.

In accordance with yet another aspect of the present invention, a plasma processing system is provided. The system includes a plasma processing chamber with a vacuum pump and gas regulator for gas flow control. A source power electrode is positioned within the processing chamber, and a bias power electrode connects to a substrate. A frequency generator produces power pulse cycles, with each cycle including pulses to both electrodes at the same frequency, followed by delay times based on gas flow rate, vacuum pump speed, and processing chamber volume.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a process flowchart of an example plasma etching process, in accordance with an embodiment;

FIG. 2A-2C illustrate schematic timing diagrams of example plasma etching process with different variations of source power and bias power status, in accordance with various embodiments;

FIG. 3 illustrates a schematic timing diagram of another example plasma etching process, in accordance with an embodiment;

FIG. 4 illustrates a schematic timing diagram of yet another example plasma etching process, in accordance with an embodiment;

FIG. 5 illustrates a schematic timing diagram of yet another example plasma etching process, in accordance with an embodiment;

FIG. 6 illustrates a schematic timing diagram of yet another example plasma etching process, in accordance with an embodiment;

FIG. 7A-7E illustrate cross-sectional views of a plasma etching process on a substrate, in accordance with an embodiment;

FIG. 8 illustrates a plasma system for performing a process of semiconductor fabrication, in accordance with an embodiment.

### DETAILED DESCRIPTION OF ILLUSTRATIVE EMBODIMENTS

This application relates to fabrication of semiconductor devices, for example, integrated circuits comprising semiconductor devices, and more particular to air gap and backside power delivery network implementations in advanced technology nodes of 5 nm and below. The fabrication of such devices may generally require etching in confined areas (<10 nm space critical dimension) and high aspect ratio features, such as contact holes, of a circuit element. Features with an aspect ratio (the ratio of height to width of the feature) greater than 10:1 are generally considered to be high aspect ratio features although many challenging etches involves much higher aspect ratios such as 50:1 and above.

Conventional plasma etching processes often struggle with insufficient removal of etch byproducts from confined areas. As a result, accumulated byproducts may reduce etch rates by physically obstructing reactive species and ions, potentially leading to undesired etch stop, where the process halts before reaching the desired depth. This can result in low yield in high aspect ratio structure fabrication and potential device performance failures.

As feature sizes continue to shrink and aspect ratios increase, effective byproduct management becomes increasingly important. A new process approach for mitigating etch byproduct redeposition in standard process chemistries that can be applied for etching of high aspect ratio features may therefore be desired. Embodiments of the present application disclose methods of fabricating high aspect ratio features by a plasma etching process based on a combination of source power and bias power control, enabling efficient etch byproduct evacuation for improved etch performance.

The plasma etching methods described in this disclosure may overcome various challenges posed for plasma etching processes for high aspect ratio features. In various embodiments, the plasma etching process may advantageously adjust pulsed source power and bias power based on characteristics of process chamber, vacuum pump and processing gases to enable sufficient etch by-product evacuation from the plasma etching chamber during the plasma etching process. This feature may improve wafer throughput and the process may be cost-effective. In addition, the method's compatibility with existing process chemistries ensures broad applicability in various semiconductor fabrication processes, making it a promising solution for next-generation device fabrication with challenging high aspect ratio features.

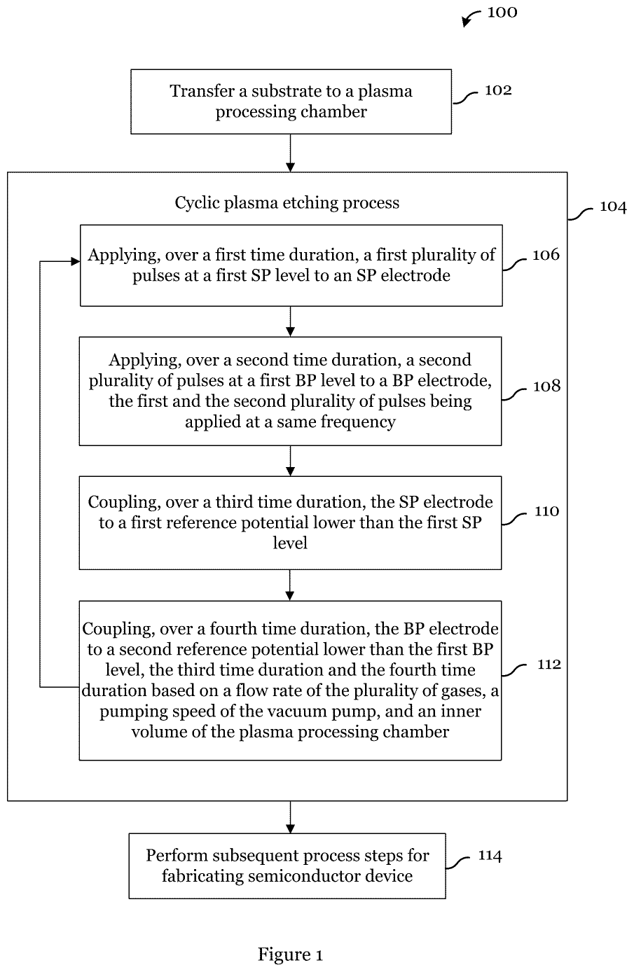

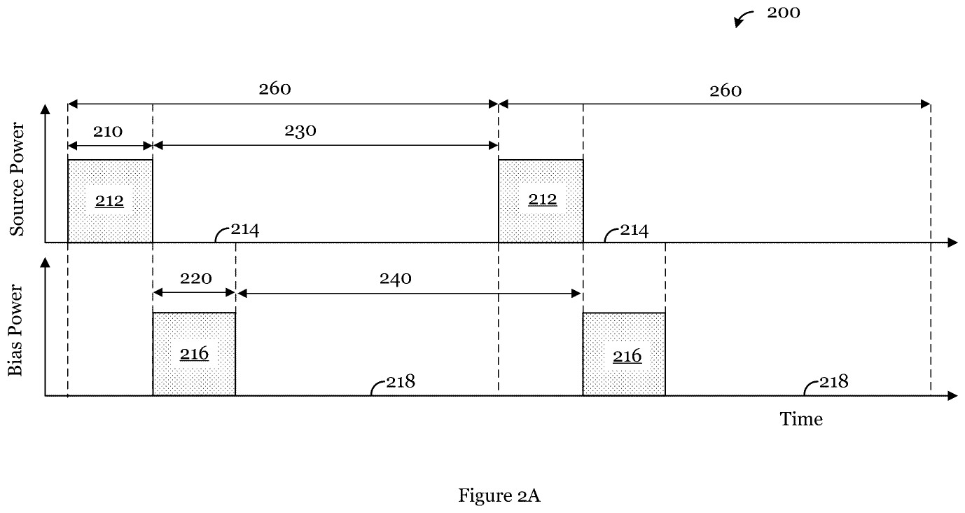

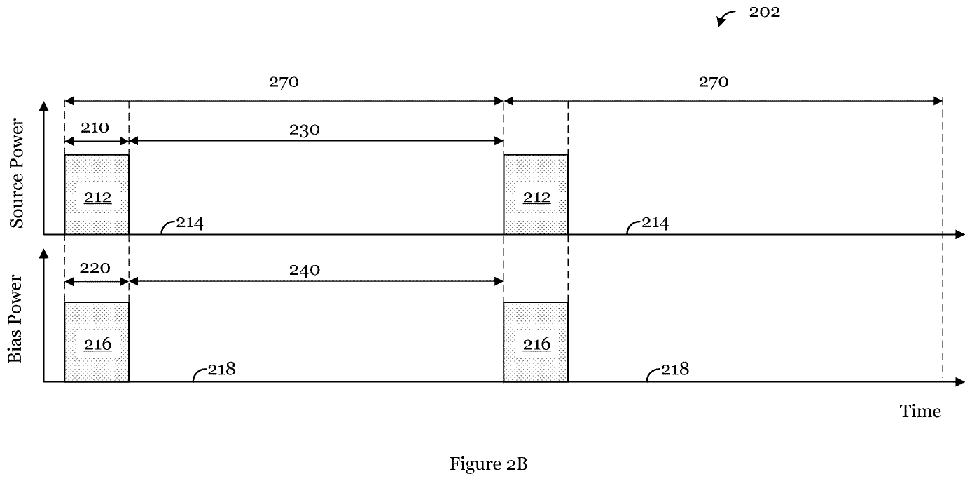

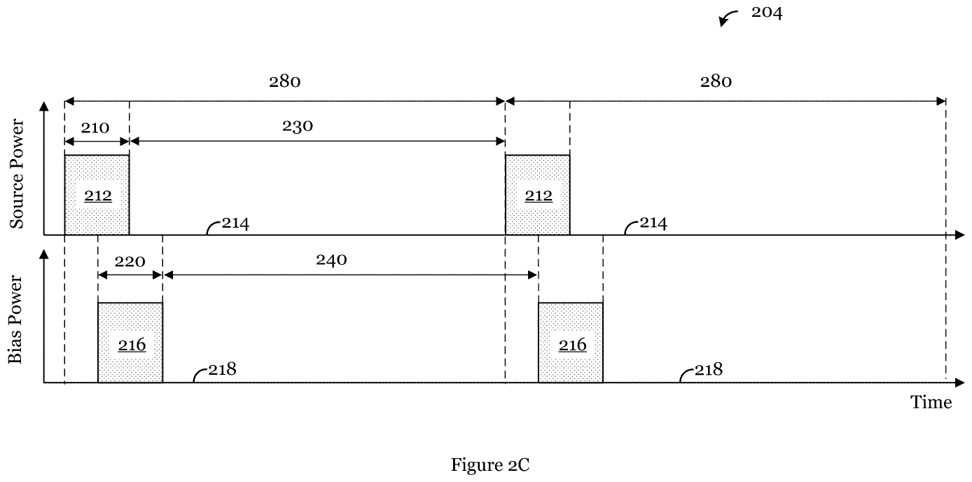

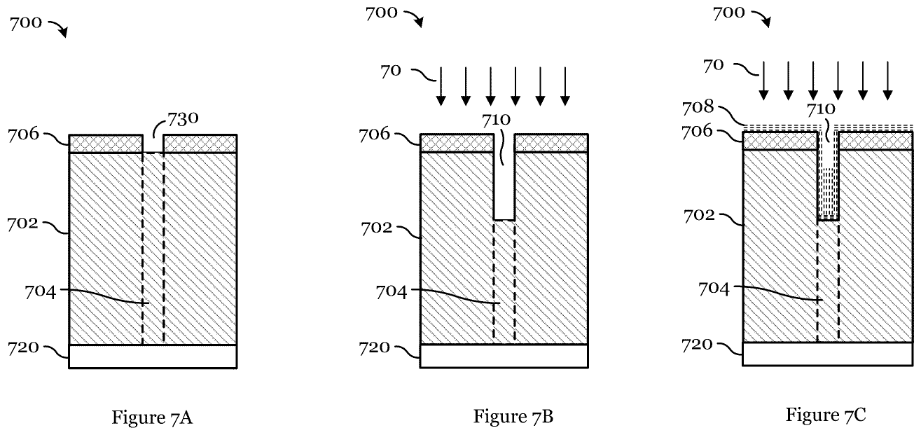

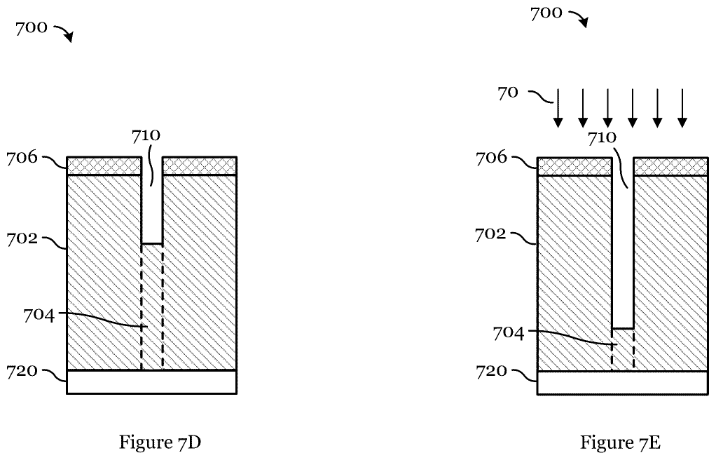

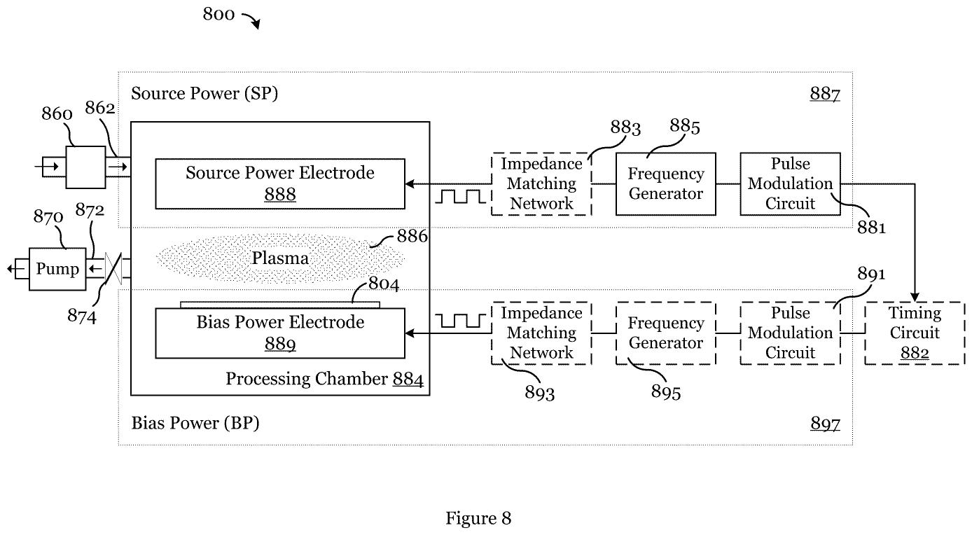

Embodiments provided below describe various systems and methods for plasma etching processing, and in particular, systems and methods for plasma etching processing that include applying pulsed source power and bias power to modulate plasmas. The following description describes the embodiments. FIG. 1 is used to describe an embodiment plasma etching processing method. FIGS. 2A-6 are used to describe various embodiments of schematic timing diagrams in a plasma etching process. FIGS. 7A-7E are used to describe an example plasma etching process on a substrate. An embodiment plasma processing system is described using FIG. 8.

FIG. 1 illustrates a process flowchart of a plasma etching process 100, in accordance with one embodiment. The plasma etching process 100 may begin with a step described in block 102 by transferring a substrate to a plasma processing chamber. In some embodiments, the substrate may comprise a region-to-be-etched with a high aspect ratio over 10:1, and in another embodiment over 50:1. A vacuum pump may be coupled to the plasma processing chamber to evacuate the plasma processing chamber. While powering the vacuum pump, a plurality of gases may be flowed into the plasma processing chamber.

Afterwards, a cyclic plasma etching process 104 may be initiated. In some embodiments, the cyclic plasma etching process 104 may comprise a plurality of cycles with each cycle comprising steps described in blocks 106, 108, 110 and 112 to achieve the desired etching results.

The block 106 may comprise applying a first plurality of power pulses to a Source Power (SP) electrode over a first time duration in the plasma processing chamber. The first plurality of power pulses may comprise a first SP level that may be optimized to efficiently ionize the plurality of gases and create a stable plasma.

In some embodiments, the plurality of gases may comprise fluorocarbons such as CH₃F (methyl fluoride) and CF₄ (tetrafluoromethane), as well as other gases tailored to the specific etching requirements. The plurality of gases may include additional fluorocarbons like C₄F₈ (octafluorocyclobutane) or C₄F₆ (hexafluoro-1,3-butadiene), which provide different carbon-to-fluorine ratios for tuning etch selectivity and profile control. In one embodiment, oxygen (O₂) may be added to enhance the removal of carbon-based byproducts and control the polymer formation on feature sidewalls. Argon (Ar) or other inert gases may be included to assist in physical sputtering and plasma stability. The specific gas mixture and ratios may be carefully selected based on the materials being etched, desired etch profile, selectivity requirements, and overall process goals.

Next, shown in block 108, over a second time duration, a second plurality of power pulses may be applied to a Bias Power (BP) electrode coupled to the substrate. The second plurality of power pulses may comprise a first BP level and function to accelerate ions of the plasma toward the substrate. The acceleration of ions may help achieve directional etching and control the etch profile. In some embodiments, the first and the second plurality of pulses may be applied at a same frequency.

The high aspect ratio of region-to-be-etched in the substrate may lead to etch byproduct accumulation within etched recess, potentially impeding further etching progress. In various embodiments, the etch byproduct may be gaseous but may redeposit within the recess, choking the recess from further etching. To allow for effective etch byproduct evacuation, the SP electrode may be coupled to a first reference potential lower than the first SP level over a third time duration (block 110). In some embodiments, the first reference potential may be coupled to ground potential while in other embodiments the first reference potential may be floating, creating a plasma-off period which allows for cessation of etching and facilitating etch byproduct evacuation.

In some embodiments, the cyclic plasma etching process may further comprise coupling, over a fourth time duration, the BP electrode to a second reference potential lower than the first BP level (block 112). The reduced power level allows for further reducing ion bombardment towards the substrate and helps in managing effective byproduct removal. In some embodiments, the second reference potential may be coupled to a ground potential while in other embodiments the second reference potential may be floating.

The third time duration and the fourth time duration may be determined based on a flow rate of the plurality of gases, a pumping speed of the vacuum pump, and an inner volume of the plasma processing chamber. These parameters allow for optimized control of the plasma and etch byproduct evacuation during the etching process. These time durations enabling etch byproduct evacuation (Tₑ) may be calculated using the following equation:

$${T}_{e} = α \frac{V}{S ( 1 + β \frac{Q}{S} )} \qquad ( Equation 1 )$$

where α is a process-specific constant between 0.1 and 1, β is a gas flow factor between 0 and 1, V is the inner volume of the plasma processing chamber, S is the pumping speed of the vacuum pump, and Q is the flow rate of the plurality of gases.

The process-specific constant α allows for fine-tuning based on factors such as plasma density, temperature, and specific etch requirements. The constant α may be determined empirically for each process.

The term v/s represents the characteristic pump-down time of the plasma processing chamber, which is the time required to evacuate the plasma processing chamber volume once. This factor ensures that the pulse duration is long enough to allow for sufficient etch byproduct removal from the plasma processing chamber.

The term

$$1 + β \frac{Q}{S}$$

represents the impact of gas flow rate on the time duration. A faster flow rate of the plurality of gases may dilute the etch byproduct more quickly, reducing their concentration in the plasma processing chamber. Therefore, higher gas flow rate value may lead to a shorter time duration to evacuate the etch byproduct. The constant β may be used to account for the increased difficulty of etch byproduct removal from higher aspect ratio structures. The higher aspect ratio of the region-to-be-etched may lead to lower β value which increases the time duration Tₑ. The constant β may be determined empirically depending on the substrate feature and gas chemistry for each process.

While Equation 1 provides a framework for determining the third and the fourth time durations, it is noted that this relationship is not exclusive. The relation in Equation 1 between duration Tₑ and V, S, Q may include linear, polynomial, or exponential functions. The optimal relationship may be determined through a combination of theoretical modeling and empirical optimization for each specific etch process and device structure. Furthermore, machine learning algorithms may be employed to refine these relationships based on accumulated process data, allowing for continuous improvement in etch performance and byproduct management.

In various embodiments, the third and the fourth time durations may be dynamically adjusted during the etching process based on real-time measurements of chamber conditions or etch progress. This adaptive approach may account for the dynamic changes of factors such as temperature, gas chemistry, aspect ratio of substrate during the plasma etching process to allow for improved etch uniformity and byproduct management.

The cyclic plasma etching process 104 may be repeated multiple times to achieve the desired etch depth and profile. The number of cycles and the specific parameters for each pulse may be adjusted based on the particular etching requirements of the substrate.

After completing the cyclic plasma etching process 104, subsequent process steps for fabricating the semiconductor device may be performed (block 114). These steps may include, but are not limited to, additional etching processes, cleaning processes, deposition processes, or other semiconductor fabrication processes.

Referring to FIG. 2A, a schematic timing diagram 200 includes Source Power (SP) and Bias Power (BP) over time is illustrated, showing a complete cycle 260 of the process, in accordance with an embodiment. The cycle 260 may be an advanced pulsing technique (APT) applied to a capacitively coupled plasma (CCP) system or an inductively coupled plasma (ICP) system. In various embodiments, the cycle 260 may be repeatedly performed (e.g. cyclically). For example, the cycle 260 may be performed many times (e.g. >>1), the exact number of times depending on the specific objectives of a chosen plasma process.

In a first time duration 210, a first power pulse 212 may be applied to the SP electrode in a duration between 1 μs and 10 ms. In various embodiments, the first power pulse 212 may comprise a plurality of power pulses. In various embodiments, the first power pulse 212 may comprise radio frequency pulses. In some embodiments, the first power pulse 212 may comprise a waveform of rectangular shape with a first SP level. The first power pulse 212 may generate a stable plasma by ionizing the plurality of gases in the plasma processing chamber. The energetic plasma comprising reactive species such as ions and radicals formed during this time duration may initiate the etching process. During the first time duration 210, the BP level may remain low or off, as indicated by the absence of a corresponding power pulse applied to the BP electrode. This time duration may focus on plasma generation and chemical reactions rather than ion acceleration, setting a stage for subsequent time durations where ion bombardment may be more precisely controlled.

In some embodiments, a second time duration 220 may follow the first time duration 210, the second time duration 220 may comprise applying a second power pulse 216 to the BP electrode with a first BP level. In various embodiments, the second power pulse 216 may comprise a plurality of power pulses. In various embodiments, the second power pulse 216 may comprise radio frequency pulses. In some embodiments, the second power pulse 216 may be a rectangle in the BP waveform to accelerate ions towards the substrate surface and enhance directional etching. In some embodiments, there may be a time gap between the first time duration 210 and the second time duration 220. In some embodiments, the first power pulse 212 and the second power pulse 216 may be applied at a same frequency.

During a third time duration 230, the SP electrode may be coupled to a first reference potential node 214 coupled to the first reference potential. The third time duration 230 may have partial overlap with the second time duration 220. The first reference potential may be lower than the first SP level, reducing the plasma density for improved control over the ion energetics in the plasma for selective etching of the substrate. In some embodiments, the first reference potential node 214 may be floating.

In a fourth time duration 240, the BP electrode may be coupled to a second reference potential node 218 coupled to a second reference potential. The fourth time duration 240 may follow sequentially with the second time duration 220. The second reference potential may be lower than the first BP level. In some embodiments, the second reference potential may be floating. The second reference potential node 218, combined with the first reference potential node 214, enables effective evacuation of etch byproduct generated during the previous etching process. The reduced plasma density and ion energy facilitate the diffusion of byproducts out of high aspect ratio features, and prevent redeposition. The third and the fourth time durations may be determined based on the various factors described above, and in one embodiment following Equation 1 as described above. In some embodiments, the third and the fourth time durations may be between 1 ms and 10 s.

The duty cycle in the context of this plasma etching process refers to the percentage of time during which a power pulse is applied to the SP or BP electrode relative to the total duration of a complete cycle. In various embodiments, the duty cycle may vary widely depending on specific application requirements, process conditions, and the characteristics of the features being etched. For example, the duty cycle may range from as low as about 3% to as high as about 90%. Lower duty cycles, such as 3% to 30%, may be employed when extended plasma off-times are necessary for thorough byproduct evacuation from high aspect ratio structures. Higher duty cycles, such as 70% to 100%, may be used for more aggressive etching when byproduct accumulation is less problematic. During the plasma etching process described herein, the duty cycles may be dynamically tuned for optimal performance across a wide range of scenarios, balancing factors such as etch rate, selectivity, and byproduct management. In some embodiments, the SP and BP electrodes may operate with different duty cycles within the same plasma etching process.

While FIG. 2A illustrates a cycle comprising four time durations (such as first time duration 210, second time duration 220, third time duration 230, and fourth time duration 240), it should be understood that the number of time durations in a cycle may vary in different embodiments. Some implementations may utilize fewer time durations, such as a two-time duration or three-time duration cycle, while others may incorporate additional time durations for more nuanced control over the etch process. Furthermore, the timing and synchronization of the SP and BP pulses may be adjusted based on specific etching requirements. For example, the first power pulse 212 and the second power pulse 216 may be asynchronized. In another example, in some embodiments, the first power pulse 212 and the second power pulse 216 may be synchronized to occur simultaneously, or they may be partially overlapped to achieve particular etching characteristics. The power levels of both SP and BP can also have multiple combinations beyond those shown in FIG. 2A. These combinations may include, but are not limited to, graduated power levels, multiple high and low power states within a single cycle, or more complex waveforms designed to optimize particular aspects of the etch process. This flexibility in time duration configuration, pulse synchronization, and power level combinations allows for fine-tuning of the plasma etching process to meet diverse requirements across different materials, substrate geometries, and etch objectives.

FIG. 2B represents a schematic timing diagram variation 202 of the timing diagram 200 in FIG. 2A, in accordance with an embodiment. The timing diagram 202 shows a synchronized application of power pulses to BP and SP electrodes in a cycle 270 which may be repeatedly performed.

The first time duration 210 and the second time duration 220 may overlap with each other and comprise applying the first power pulse 212 to the SP electrode being synchronized with applying the second power pulse 216 to the BP electrode. This synchronization allows for precise control over both plasma generation and ion bombardment for enhanced etch rates and directionality. In some embodiments, the first power pulse 212 and the second power pulse 216 may comprise radio frequency pulses.

In the following third time duration 230, which may overlap with the fourth time duration 240, both SP and BP may be reduced to floating or lower levels, represented by the first reference potential node 214 and the second reference potential node 218, respectively. The third time duration 230 may serve a dual purpose of allowing for byproduct evacuation and thermal management of the substrate. The third time duration 230 may be optimized based on the volume of processing chamber, the pumping speed of vacuum pump, and the flow rate of plurality of gases as previously discussed.

FIG. 2C illustrates yet another schematic timing diagram variation 204, in accordance with one embodiment. The power pulses applied to the SP electrode and the BP electrode may be partially synchronized, offering a more nuanced approach to plasma control. In various embodiments, the cycle 280 may be repeatedly performed (e.g. cyclically). For example, the cycle 280 may be performed many times (e.g. >>1), the exact number of times depending on the specific objectives of a chosen plasma process.

The first time duration 210 may begin with the application of the first power pulse 212 to the SP electrode without applying power pulse to the BP electrode. This may allow for the establishment of a high-density plasma before ion acceleration begins. During the application of the first power pulse 212, the second power pulse 216 may be applied in a second time duration 220, creating a period of controlled, directional etching. The first time duration 210 and the second time duration 220 may be partially overlapped. Afterwards, the SP electrode may be coupled to the first reference potential node 214 coupled to the first reference potential in the third time duration 230. Following the second time duration 220, the BP electrode may be coupled to the second reference potential node 218 coupled to the second reference potential, allowing for etch byproduct evacuation.

It is noted that while the power pulses with waveform of rectangular shape are depicted in various embodiments of FIGS. 2A-2C for clarity, the actual waveforms may take various shapes in different implementations. These shapes may include, but are not limited to, trapezoidal, triangular, sinusoidal, or custom-designed waveforms. The specific pulse shape may be selected based on process requirements, plasma characteristics, or equipment capabilities to optimize etch performance and byproduct management. Furthermore, the transitions between power levels may not be instantaneous as shown, but could involve controlled ramp-up and ramp-down periods to manage plasma stability and reduce potential damage from sudden power changes.

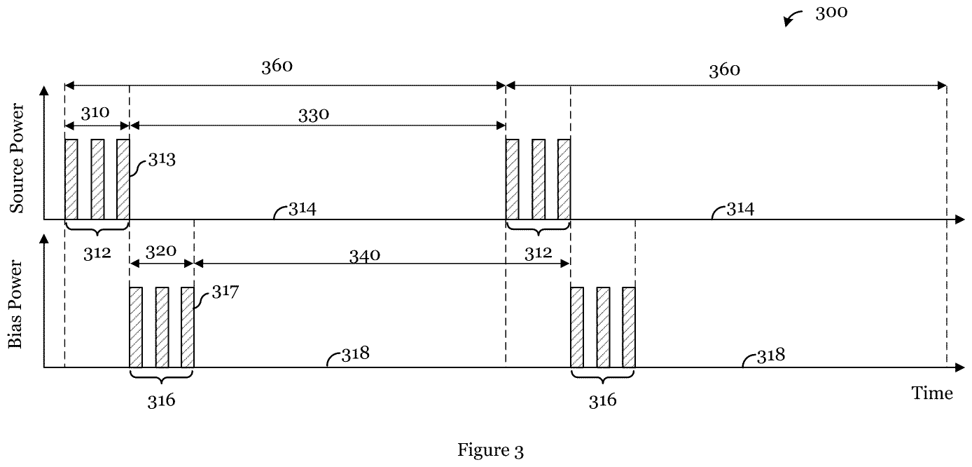

FIG. 3 represents another schematic timing diagram 300 including SP and BP over time, showing a complete cycle 360 of the process, in accordance with an embodiment. FIG. 3 differs from FIGS. 2A-2C in the configuration of a first power pulse 312 and a second power pulse 316, which may comprise a plurality of high-frequency spikes, instead of continuous rectangular pulses. In various embodiments, the cycle 360 may be repeatedly performed (e.g. cyclically) depending on the specific objectives of a chosen plasma process.

In some embodiments, a first power pulse 312 may be applied to the SP electrode during a first time duration 310, the first power pulse 312 comprising a plurality of SP spikes 313. Each SP spike 313 may be a pulse made of high frequency signal between 1 kHz and 20 MHz (for example, at frequencies of 400 kHz, 900 kHz, 1 MHz, 13 MHz, or other frequencies within this range). In other words, the first time duration 310 may be the time, the high frequency signal applied on the SP electrode is ON during each cycle. Alternatively, each SP spike 313 may comprise a train of DC pulses. These rapid, high-intensity spikes may generate short bursts of high-density plasma. The use of spikes in the power pulse waveform offers several advantages in plasma etching. The rapid on-off in spikes may help maintain a more stable plasma, reducing the likelihood of mode transitions or instabilities. Additionally, these short, intense pulses may lead to more efficient power transfer to the plasma, potentially reducing overall power consumption.

In some embodiments, a second power pulse 316 may be applied to the BP electrode during a second time duration 320, the second power pulse 316 comprising a plurality of high-frequency BP spikes 317. The BP spikes 317 may advantageously reduce the flux of ions with wide angular distribution, maintaining more consistent ion directionality during the etch process. The BP spikes 317 may also allow for a more tailored ion energy distribution, potentially enhancing etch anisotropy and reducing damage to underlying layers. Rapid cycling of the bias power during application of BP spikes may help mitigate charge accumulation on the substrate surface, which is particularly beneficial for etching high-aspect-ratio features in insulating materials. The BP spikes 317 may comprise similar characteristics of the SP spikes 313 as described above.

In some embodiments, the third time duration 330 and the fourth time duration 340 may maintain similar characteristics to their counterparts in FIG. 2A. The SP electrode may be coupled to a first reference potential node 314 coupled to the first reference potential and the BP electrode may be coupled to a second reference potential node 318 coupled to the second reference potential. In some embodiments, the second reference potential may be coupled to a ground potential while in other embodiments the first reference potential may be floating. The third time duration 330 and the fourth time duration 340 may provide periods of lower or ground potential power pulse for etch byproduct evacuation. In some embodiments, the third time duration 330 and the fourth time duration 340 may be determined based on the various factors described above, and in one embodiment following Equation 1 as described with reference to FIG. 2A.

While FIG. 3 illustrates an asynchronous application of the first power pulse 312 and second power pulse 316, it is important to note that this configuration represents just one possible timing arrangement. In various embodiments, these power pulses may be applied in different synchronization patterns to achieve specific etching outcomes. For example, the first and second power pulses to the SP and BP electrodes may be asynchronized. In other example, the first and second power pulses to the SP and BP electrodes may be fully synchronized, with both the first power pulse 312 and the second power pulse 316 starting and ending simultaneously. Alternatively, a partially synchronized approach may be employed, where there is some overlap between the first and the second power pulses 312 and 316, allowing for fine-tuning of the plasma characteristics and ion bombardment energy.

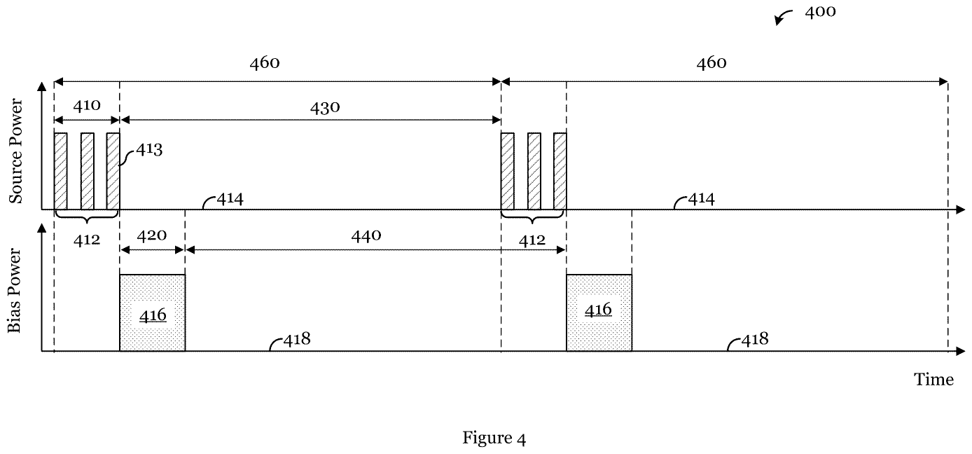

FIG. 4 illustrates another schematic timing diagram 400 showing a complete cycle 460 of the plasma etching process, in accordance with an embodiment. The timing diagram 400 differs from the timing diagram 300 with different power pulses applied to the BP electrode.

Similar to FIG. 3, a first power pulse 412 may be applied to the SP electrode in a first time duration 410, the first power pulse 412 comprising a plurality of SP spikes 413. The SP spikes 413 may maintain the characteristics described for the SP spikes 313 with reference to FIG. 3, generating short bursts of high-density plasma with the associated benefits of plasma stability and efficient power transfer.

During a second time duration 420 in FIG. 4, a continuous second power pulse 416 may be applied to the BP electrode. The second power pulse 416 may provide sustained ion acceleration towards the substrate, potentially offering more consistent ion bombardment energy throughout this time duration. In some embodiments, the second power pulse 416 may comprise a plurality of power pulses. In various embodiments, the second power pulse 416 may comprise radio frequency pulses.

A third time duration 430 and a fourth time duration 440 in FIG. 4 may correspond to the durations for etch byproduct evacuation, similar to the third time duration 330 and the fourth time duration 340 described FIG. 3. During these periods, the SP electrode may be coupled to a first reference potential node 414 coupled to the first reference potential which may be floating, and the BP electrode may be coupled to a second reference potential node 418 coupled to the second reference potential which may be floating to facilitate etch byproduct removal. In some embodiments, the first reference potential may be lower than the level of the first power pulse 412. In some embodiments, the second reference potential may be lower than the level of the second power pulse 416.

In various embodiments, the second power pulse 416 may take on waveforms other than rectangle, such as trapezoidal, triangular, or sinusoidal shapes. Additionally, the first power pulse 412 and second power pulse 416 may be asynchronized, fully or partially synchronized in some implementations, allowing for precise control and fine-tuning of plasma characteristics and ion bombardment energy. This flexibility in pulse shaping and timing enables optimization of the etching process for different materials and substrate geometries.

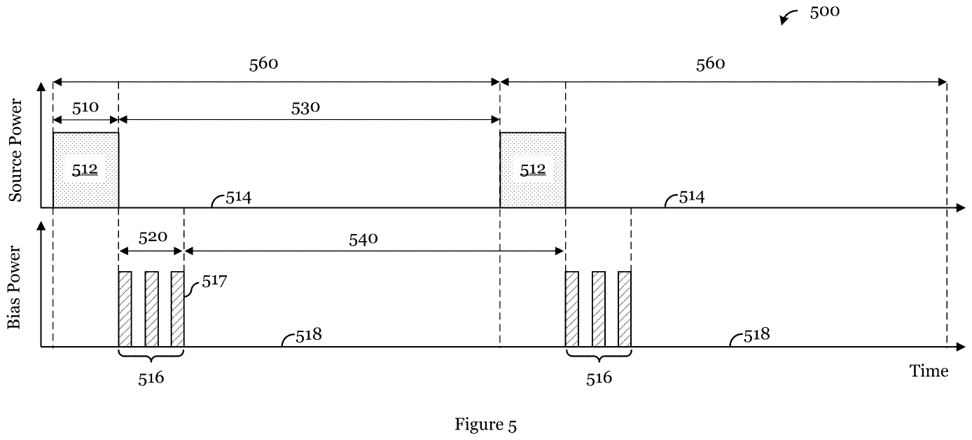

FIG. 5 illustrates a schematic timing diagram 500 depicting another variation of the plasma etching process, showing a complete cycle 560, in accordance with an embodiment. The timing diagram 500 differs from the timing diagram 300 in different power pulses applied to the SP electrode.

In some embodiments, a continuous first power pulse 512 may be applied to the SP electrode during a first time duration 510. The first power pulse 512 may provide sustained high-density plasma generation, potentially offering more stable plasma characteristics throughout this duration. In some embodiments, the first power pulse 512 may comprise a plurality of power pulses. In various embodiments, the first power pulse 512 may comprise radio frequency pulses. During a second time duration 520, a second power pulse 516 comprising a plurality of BP spikes 517 may be applied to the BP electrode. The BP spikes 517 may maintain the characteristics and advantages described for the BP spikes 317 with reference to FIG. 3.

A third time duration 530 and a fourth time duration 540 in FIG. 5 may correspond to the durations for etch byproduct evacuation, similar to the equivalent periods described in previous figures. During these periods, the SP electrode may be coupled to a first reference potential node 514 coupled to the first reference potential, which may be floating. The BP electrode may be coupled to a second reference potential node 518 coupled to the second reference potential, which may be floating. These lower power levels applied to both SP and BP electrodes may facilitate etch byproduct removal. In some embodiments, the first reference potential may be lower than the level of the first power pulse 512. And in some embodiments, the second reference potential may be lower than the level of the second power pulse 516

While FIG. 5 shows rectangular pulses for the first power pulse 512 and BP spikes 517 for the second power pulse 516, in some embodiments, these pulses may take on different waveforms. For example, the first power pulse 512 may have trapezoidal, triangular, or sinusoidal shapes. Additionally, although FIG. 5 depicts a specific timing relationship between the SP and BP pulses, in some embodiments, these pulses may be asynchronized, fully or partially synchronized. This flexibility in pulse shaping and synchronization allows for fine-tuning of plasma characteristics and ion bombardment energy to meet specific process requirements.

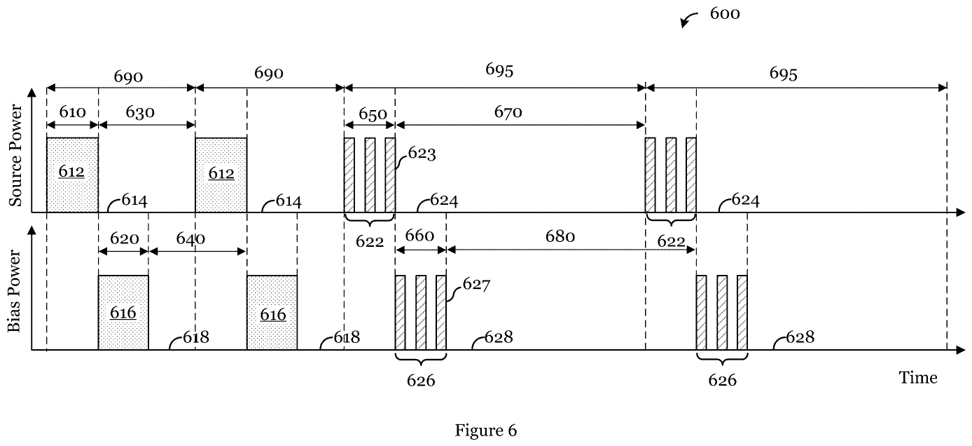

FIG. 6 illustrates a schematic timing diagram 600 of another example plasma etching process that combines different types of cycles, in accordance with an embodiment. This configuration demonstrates mixing varying cycle structures to optimize both etching performance and byproduct management.

In some embodiments, the diagram 600 may comprise a cycle 690 and a cycle 695. The cycle 690 may be characterized by shorter durations for etch byproduct evacuation (higher frequency), focusing primarily on effective plasma etching, while the cycle 695 features extended durations for etch byproduct evacuation (lower frequency), focusing primarily on effective byproduct evacuation.

In some embodiments, a first power pulse 612 may be applied to the SP electrode, during a first time duration 610 of the cycle 690. In various embodiments, the first power pulse 612 may comprise radio frequency pulses. A second time duration 620 may follow, during which a second power pulse 616 may be applied to the BP electrode. In various embodiments, the second power pulse 616 may comprise radio frequency pulses. During a third time duration 630 of the cycle 690, the SP electrode may be coupled to a first reference potential node 614 coupled to the first reference potential which may be floating, or lower than the level of the first power pulse 612. And during a fourth time duration 640 of the cycle 690, the BP electrode may be coupled to a second reference potential node 618 coupled to the second reference potential which may be floating, or lower than the level of the second power pulse 616. In some embodiments, the third time duration 630 and the fourth time duration 640 of the cycle 690 may be shorter than the corresponding time durations described in previous figures, leading to higher plasma etching rate with limited etch byproduct evacuation. In some embodiments, the third time duration 630 and the fourth time duration 640 may be in a range of 1 μs and 10 ms. The cycle 690 may be repeatedly performed until targeted etching profile is achieved.

In some embodiments, the cycle 695 may follow the cycle 690 and begin with a fifth time duration 650, during which a third power pulse 622 comprising a plurality of high-frequency spikes 623 may be applied to the SP electrode. Afterwards, a sixth time duration 660 of the cycle 695 may feature a fourth pulse 626 applying to the BP electrode. The fourth power pulse 626 may comprise a plurality of spikes 627 with similar high-frequency, potentially providing precise control over ion bombardment energy and directionality.

A seventh time duration 670 of the cycle 695 may follow, focusing on thorough byproduct evacuation. During a seventh time duration 670, the SP electrode may be coupled to a third reference potential node 624 coupled to the first reference potential, which may be floating, or lower than the level of the third power pulse 622. During an eighth time duration 680, the BP electrode may be coupled to a fourth reference potential node 628 coupled to the second reference potential, which may be floating or lower than the level of the fourth power pulse 626. In some embodiments, the seventh time duration 670 and the eighth time duration 680 may be determined based on the various factors described above, and in one embodiment following Equation 1 as described previously, allowing for sufficient time to evacuate etch byproducts from the processing chamber. In some embodiments, the seventh time duration 670 and the eighth time duration 680 may be in a range of 1 ms to 10 s.

In some embodiments, the specific sequence and frequency of alternating between the cycles 690 and 695 may be tailored based on factors such as the material being etched, substrate geometry, and overall process requirements. In some embodiments, the first, the second, the third, and the fourth power pulses 612, 616, 622, and 626 may take on waveforms with various shapes such as rectangular, trapezoidal, triangular, or sinusoidal shapes, allowing for even more refined process control. In some embodiments, the first, the second, the third, and the fourth power pulses 612, 616, 622, and 626 may be asynchronized, partially or fully synchronized.

FIGS. 7A-7E illustrate cross-sectional views of a plasma etching process on a substrate 700 in a plasma processing chamber, in accordance with an embodiment.

FIG. 7A shows the initial structure before etching begins. The substrate 700 may comprise a layer-to-be-etched 702 disposed over an underlying layer 720. The underlying layer 720 may comprise a bulk substrate such as a blank silicon wafer, a silicon-on-insulator (SOI) wafer, or any of various other semiconductor substrates. The underlying layer 720 may also comprise any number of additional materials, including compound semiconductors, metal or metal oxides, or metal nitrides. The underlying layer 720 may include any material portion or structure of a device, particularly a semiconductor or other electronics device. The underlying layer 720 may serve as a foundation for the layer-to-be-etched 702 which is the subject of plasma etching processing. The layer-to-be-etched 702 may comprise group 3-5 semiconductors, metals, oxides, carbides, nitrides, polymers, or any other materials suitable for etching.

In some embodiments, a mask layer 706 may be disposed over the layer-to-be-etched 702 to define an etch region 730. The ions in the plasma may etch a region-to-be-etched 704 of the layer-to-be-etched 702 through the etch region 730. In some embodiments, the region-to-be-etched 704 may comprise a high aspect ratio of at least 10:1, forming a deep trench or via.

The mask layer 706 may comprise silicon oxide in one embodiment. In various embodiments, the mask layer 706 may comprise silicon nitride, silicon carbonitride (SiCN), or silicon oxycarbide (SiOC). In alternate embodiments, the mask layer 706 may comprise titanium nitride. In one or more embodiments, the mask layer 706 may comprise other suitable organic materials such as spin-on carbon hard mask (SOH) materials. Further, the mask layer 706 may be a stacked hard mask comprising, for example, two or more layers using two different materials. In some of such embodiments, the first hard mask of the mask layer 706 may comprise a metal-based layer such as titanium nitride, titanium, tantalum nitride, tantalum, tungsten based compounds, ruthenium based compounds, or aluminum based compounds, and the second hard mask material of the mask layer 706 may comprise a dielectric layer such as silicon oxide, silicon nitride, SiCN, SiOC, silicon oxynitride, or silicon carbide. The mask layer 706 may be deposited using suitable deposition techniques such as vapor deposition including chemical vapor deposition (CVD), physical vapor deposition (PVD), as well as other plasma processes such as plasma enhanced CVD (PECVD), sputtering, and other processes including wet processes. The mask layer 706 may have a thickness of about 5 nm to about 50 nm in various embodiments. In one or more embodiments, an additional layer such as silicon-containing anti-reflective coating films (SiARC) or other ARC films may be formed over the mask layer 706. In further embodiments, a photoresist that may have been used to pattern the mask layer 706 by lithography may be left over the mask layer 706.

Before the etching process starts, a vacuum pump may be coupled to the plasma processing chamber to evacuate the plasma processing chamber and reach the required pressure. While powering the vacuum pump, the plurality of gases may be flowed into the plasma processing chamber. The plurality of gases may comprise the species as described for the gases in block 106 with reference to FIG. 1.

In FIG. 7B, a cyclic plasma etching process 70 may be initiated, utilizing the power pulsing techniques detailed in FIGS. 2A-6. The cyclic plasma etching process 70 may comprise applying a series of power pulses to the SP electrode and the BP electrode, following the timing diagrams previously described, such as the timing diagrams 200, 300, 400, 500 or 600. For example, a first power pulse, which may correspond to the first power pulses 212, 312, 412, 512, or 612 in earlier figures, may be applied to the SP electrode to generate a high-density plasma from the plurality of gases. This may be followed by, partially or fully overlapped with, a second power pulse applied to the BP electrode, wherein the power pulse may follow the second power pulses 216, 316, 416, 516, or 616 in previous figures to direct and accelerate reactive species and ions from the plasma towards the substrate 700.

The arrows in FIG. 7B represent bombardment of reactive species and ions onto the exposed surface of the substrate 700. As the plasma interacts with the region-to-be-etched 704 through the etch region 730 defined by the mask layer 706, a recess 710 may begin to form in the layer-to-be-etched 702. The areas protected by the mask layer 706 remain intact during this process. The specific time durations, power levels, and synchronization patterns of the power pulses applied to the SP and BP electrodes may be dynamically adjusted according to the various timing diagrams described in FIGS. 2A-6. These may include, but are not limited to, continuous pulses, spike-like pulses, fully asynchronized, fully synchronized or partially overlapped pulses, and alternating cycles optimized for etching and byproduct evacuation. The flexibility to employ different pulsing strategies, as illustrated in the previous figures, allows for precise control over the etch profile, rate, and byproduct management, particularly benefiting the etching of regions of high aspect ratio.

FIG. 7C illustrates the issue of etch byproduct accumulation during the etching process. As the plasma etching progresses and the recess 710 deepens, etch byproduct 708, shown as dotted patterns, may start to accumulate. The etch byproduct 708 may comprise volatile compounds formed from the interaction between the etchant gases and the etched material, as well as redeposited material sputtered from the surface. The byproduct may deposit on the top and sidewalls of the mask layer 706, the sidewalls of the recess 710, and potentially at the bottom of the recess 710. Such accumulation is particularly problematic in high aspect ratio features, where the limited opening restricts byproduct evacuation. The accumulation of byproducts may obstruct incoming reactive species, reducing the etch rate, especially at the bottom of the recess. Moreover, it may lead to profile distortion through redeposition on sidewalls, potentially causing tapered or bowed features instead of vertical sidewalls.

FIG. 7D represents a step in the cyclic plasma etching process to evacuate the etch byproduct 708 before resuming etching process. This step may correspond to the lower or zero power time durations in the pulsing cycles described in FIGS. 2A-6. The power pulses applied to the SP electrode and the BP electrode may be reduced before the next high-power cycle begins. In some embodiments, the level of power pulses applied to the SP electrode and the BP electrode may be floating. The reduced power level may correspond to the first reference potential or the second reference potential as described in the earlier timing diagrams. The evacuating time of this low-power or zero-power step may be optimized based on the various factors described above, and in one embodiment following the Equation 1 discussed earlier.

During evacuation, the etch byproduct 708 may be given enough time to diffuse out of the high aspect ratio recess 710 and be evacuated from the plasma processing chamber. The specific time durations and power levels of these reduced power pulses may be dynamically adjusted according to the various timing diagrams described in FIGS. 2A-6. This may include strategies such as alternating between short evacuation durations (as in cycle 690 of FIG. 6) and extended evacuation durations (as in cycle 695 of FIG. 6) to balance high etch rates with effective byproduct management.

FIG. 7E illustrates the resumption of the etching process following the etch byproduct evacuation step. With the etch byproduct 708 effectively evacuated from the recess 710, the plasma may now more efficiently reach the layer-to-be-etched 702, enabling continued etching with renewed effectiveness. The cycle depicted between FIGS. 7B and 7E may be repeated multiple times, corresponding to the alternating high-power and low-power phases in the pulsing cycles described previously. The number of cycles and the specific parameters of each cycle (such as power levels, pulse durations, and the ratio of etch time to evacuation time) may be dynamically adjusted based on real-time monitoring of the etch progress. The process may continue until the region-to-be-etched 704 is fully etched to the desired depth.

While FIGS. 7A-7E depict the formation of a trench or via, it is noted that the plasma etching process described herein may be applied to the fabrication of various other semiconductor structures. These may include, but are not limited to, fin field-effect transistor (FinFET) structures, multi-gate transistors, 3D NAND memory arrays, through-silicon vias (TSVs), interconnect structures in advanced packaging, and features in emerging technologies such as quantum devices or photonic integrated circuits. The versatility of this etching process makes it suitable for a wide range of applications in advanced semiconductor device manufacturing, where precise control over feature dimensions and profiles is needed.

FIG. 8 illustrates a block diagram of an example plasma processing system in accordance with an embodiment of the invention. The plasma processing system of FIG. 8 may be used to perform any of the embodiment methods as described herein, such as the methods of FIG. 1, for example. Furthermore, the plasma processing system of FIG. 8 may be used to implement the schematic timing diagrams to perform any of the embodiment methods as described herein, such as the schematic timing diagram of FIG. 2, for example.

Referring to FIG. 8, a plasma processing system 800 may comprise a substrate 804 disposed in a plasma processing chamber 884 inside which a plasma 886 may be generated between an SP electrode 888 and a BP electrode 889. The target substrate 804 may be electrically coupled to the BP electrode 889. For example, the BP electrode 889 may be a substrate holder and an electrostatic chuck in one embodiment.

The plasma processing chamber 884 may be configured to accommodate plasma based fabrication processes. It may be configured as a CCP system or an ICP system for etching or deposition applications. In some embodiments, the processing chamber 884 may be applied for plasma etching processes comprising reactive ion etching (RIE), atomic layer etching (ALE), deep reactive ion etching (DRIE), or the like.

A gas line 862 may be connected to the plasma processing chamber 884. A gas regulator 860 may be coupled to the plasma processing chamber 884 through the gas line 862. The gas regulator 860 may regulate the amount, flow rate and species of a plurality of gases flowing into the plasma processing chamber 884. In some embodiments, the plurality of gases may comprise fluorocarbons such as CH₃F (methyl fluoride) and CF₄ (tetrafluoromethane), as well as other gases tailored to the specific etching requirements. The plurality of gases may include additional fluorocarbons like C₄F₈ (octafluorocyclobutane) or C₄F₆ (hexafluoro-1,3-butadiene), which provide different carbon-to-fluorine ratios for tuning etch selectivity and profile control. In one embodiment, oxygen (O₂) may be added to enhance the removal of carbon-based byproducts and control the polymer formation on feature sidewalls. Argon (Ar) or other inert gases may be included to assist in physical sputtering and plasma stability.

An exhaust gas line 872 may be connected to the plasma processing chamber 884. A vacuum pump 870 may be coupled to the plasma processing chamber 884 via the exhaust gas line 872. A throttle valve 874 may be used to control the pressure of the plasma processing chamber 884. In various embodiments, the vacuum pump 870 may be a turbomolecular pump. Though not depicted in the figure, in some embodiments, there may be more than one vacuum pump coupled to the plasma processing chamber 884. The vacuum pump 870 may be powered on to evacuate the plasma processing chamber 884 during the plasma processing.

The substrate 804 may comprise a bulk substrate such as a blank silicon wafer, a silicon-on-insulator (SOI) wafer, or any of various other semiconductor substrates. The substrate may also be coated or layered with any number of additional materials, including compound semiconductors, metal or metal oxides, or metal nitrides. The substrate may include any material portion or structure of a device, particularly a semiconductor or other electronics device.

SP may be provided to the SP electrode 888 via an SP control path 887 while BP may be provided to the BP electrode 889 via a BP control path 897. SP provided to the SP electrode 888 may generate the plasma 886 within the plasma processing chamber 884. The SP control path 887 may include an SP frequency generator 885 coupled to the SP electrode 888 through an SP impedance matching network 883. The SP frequency generator 885 may be coupled to an SP pulse modulation circuit 881 which outputs a modulated source signal. The SP frequency generator 885 may superimpose a waveform (e.g. a sinusoidal waveform) onto the modulated source signal to generate power pulses that are delivered to the SP electrode 888.

Similarly, the BP control path 897 may include an optional BP frequency generator 895 coupled to the BP electrode 889 through an optional BP impedance matching circuit 893. The BP control path 897 may also include an optional BP pulse modulation circuit 891. The optional BP frequency generator 895 may be coupled to the optional BP pulse modulation circuit 891 which outputs a modulated source signal. The optional BP frequency generator 895 may superimpose a waveform (e.g. a sinusoidal waveform) onto the modulated source signal to generate power pulses that are delivered to the BP electrode 889. Both the SP frequency generator 885 and the optional BP frequency generator 895 may include an amplification circuit to allow adjustment of amplitude of power pulses during different time durations of a pulse cycle.

In some embodiments, a pulse modulation timing circuit 882 may be included to accept an input from the SP pulse modulation circuit 881 and adjust the timing of the signal modulated by the optional BP pulse modulation circuit 891. The pulse modulation timing circuit 882 may also control the timing of both the SP pulse modulation circuit 881 and the optional BP pulse modulation circuit 891.

In various embodiments, the SP frequency generator 885 and the BP frequency generator 895 may work together to generate a plurality of power pulse cycles for both the SP electrode 888 and BP electrode 889. In some embodiments, each power pulse cycle may comprise a first plurality of pulses applied to the SP electrode 888 and a second plurality of pulses applied to the BP electrode 889. In one embodiment, the first and second plurality of pulses may be produced at a same frequency, maintaining synchronization between the SP and BP signals. The SP pulse modulation circuit 881 and BP pulse modulation circuit 891 may be employed to introduce precisely controlled delay times. Specifically, a first delay time may be implemented for the plurality of pulses applied to the SP electrode 888, while a second delay time may be applied to the plurality of pulses applied to the BP electrode 889. These delay times may be determined based on various factors described above, and in one embodiment following Equation 1 described above, which is based on the flow rate of the plurality of gases introduced into the chamber (controlled via the gas regulator 860), the pumping speed of the vacuum pump 870, and the inner volume of the plasma processing chamber 884. Moreover, the timing circuit 882 may coordinate the operation of both pulse modulation circuits, ensuring that the calculated delay times are accurately applied to each pulse train.

Alternatively, the optional BP frequency generator 895 and the optional BP impedance matching circuit 893 may be omitted and BP may be directly supplied to the BP electrode 889. Such a configuration may be used with DC power is provided directly to the BP electrode 889. For example, a power pulse train may be generated at the BP electrode 889 by coupling the optional BP pulse modulation circuit 891 directly to the BP electrode 889.

In the specific case where the BP pulses may be identical to the SP pulses except for a timing offset, the BP control path 897 may use the SP pulse modulation circuit 881 and omit the optional BP pulse modulation circuit 891. However, the optional BP pulse modulation circuit 891 may advantageously enable greater flexibility regarding the pulse width, amplitude, and shape of the BP pulses compared to the SP pulses.

Although the plasma processing system 801 is illustrated as providing SP at a top electrode and BP at a bottom electrode, this does not have to be the case. For example, in an alternate configuration, the plasma processing system 801 may provide both SP and BP at the bottom electrode while the top electrode operates as a counter electrode.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of plasma etching, the method comprising:
powering on a vacuum pump to evacuate a plasma processing chamber;
while powering the vacuum pump, flowing a plurality of gases into the plasma processing chamber; and
performing a cyclic plasma etching process on a substrate within the plasma processing chamber while powering the vacuum pump and flowing the plurality of gases, the cyclic plasma etching process comprising a plurality of cycles, one of the plurality of cycles comprising:
applying, over a first time duration, a first plurality of pulses at a first SP level to an SP electrode;
applying, over a second time duration, a second plurality of pulses at a first BP level to a BP electrode, the first and the second plurality of pulses being applied at a same frequency;
coupling, over a third time duration, the SP electrode to a first reference potential lower than the first SP level; and
coupling, over a fourth time duration, the BP electrode to a second reference potential lower than the first BP level, the third time duration and the fourth time duration based on a flow rate of the plurality of gases, a pumping speed of the vacuum pump, and an inner volume of the plasma processing chamber.

2. The method of claim 1, wherein the first reference potential and the second reference potential are a floating potential.

3. The method of claim 1, wherein the first plurality of pulses is synchronized with the second plurality of pulses.

4. The method of claim 1, wherein the first plurality of pulses is asynchronized with the second plurality of pulses.

5. The method of claim 1, wherein the plurality of gases comprises CH₃F and CF₄.

6. The method of claim 1, wherein the first plurality of pulses applied to the SP electrode comprises a waveform of rectangular, trapezoidal, triangular, or sinusoidal shape.

7. The method of claim 1, the second plurality of pulses applied to the BP electrode comprises a waveform of rectangular, trapezoidal, triangular, or sinusoidal shape.

8. The method of claim 1, wherein the third time duration is between 1 ms and 10 s.

9. The method of claim 1, wherein the first plurality of pulses comprises SP spikes with a frequency between 1 kHz and 20 MHz.

10. The method of claim 1, wherein the second plurality of pulses comprises BP spikes with a frequency between 1 kHz and 20 MHz.

11. A method of etching a substrate, the method comprising:
forming a mask layer over a layer-to-be-etched of a substrate in a plasma processing chamber to define an etch region;
powering on a vacuum pump to evacuate the plasma processing chamber;
while powering the vacuum pump, flowing a plurality of gases into the plasma processing chamber;
performing a cyclic plasma etching process in the plasma processing chamber comprising:
applying a first plurality of pulses to a source power (SP) electrode to generate a plasma from the plurality of gases;
applying a second plurality of pulses to a bias power (BP) electrode to direct ions from the plasma towards the substrate, the ions etching a recess in the layer-to-be-etched through the etch region; and
evacuating etch byproducts from the plasma processing chamber, the evacuating comprising reducing power applied to the SP electrode and the BP electrode before applying the power pulse of the next cycle.

12. The method of claim 11, wherein the evacuating time is based on a flow rate of the plurality of gases, a pumping speed of the vacuum pump, and an inner volume of the plasma processing chamber.

13. The method of claim 11, wherein the plurality of gases comprises CH₃F and CF₄.

14. The method of claim 11, wherein the layer-to-be-etched comprises a region-to-be-etched with an aspect ratio of at least 10:1.

15. The method of claim 11, applying the first plurality of pulses to the SP electrode is synchronized with applying the second plurality of pulses to the BP electrode.

16. The method of claim 11, applying the first plurality of pulses to the SP electrode is asynchronized with applying the second plurality of pulses to the BP electrode.

17. The method of claim 11, wherein the first plurality of pulses applied to the SP electrode comprises a waveform of rectangular, trapezoidal, triangular, or sinusoidal shape.

18. The method of claim 11, wherein the second plurality of pulses applied to the BP electrode comprises a waveform of rectangular, trapezoidal, triangular, or sinusoidal shape.

19. A plasma processing system, the system comprising:
a plasma processing chamber;
a vacuum pump configured to be coupled to the plasma processing chamber;
a gas regulator configured to flow a plurality of gases into the plasma processing chamber;
a source power (SP) electrode within the plasma processing chamber;
a bias power (BP) electrode configured to be coupled to a substrate in the plasma processing chamber; and
a frequency generator programmed to generate a plurality of power pulse cycles, one of the plurality of power pulse cycles comprising:
a first plurality of pulses to the SP electrode;
a second plurality of pulses to the BP electrode, the first and the second plurality of pulses are at a same frequency;
a first delay time for the plurality of pulses to the SP electrode; and
a second delay time for the plurality of pulses to the BP electrode, the first delay time and the second delay time based on a flow rate of the plurality of gases, a pumping speed of the vacuum pump, and an inner volume of the plasma processing chamber.

20. The system of claim 19, wherein the plurality of gases comprises CH₃F and CF₄.
